(19) United States
(12) Patent Application Publication
(10) Pub. No.: US 2026/0096441 A1
(43) Pub. Date: Apr. 2, 2026

(54) RADIO FREQUENCY DEVICES AND METHODS FOR MANUFACTURING THEREOF

(71) Applicant: Infineon Technologies AG, Neubiberg (DE)

(72) Inventors: Alexander Michael MELZER, Alberndorf in der Riedmark (AT); Michael GERSTMAIR, Langenstein (AT)

(21) Appl. No.: 19/343,959

(22) Filed: Sep. 29, 2025

(30) Foreign Application Priority Data
Sep. 30, 2024 (DE) 1020241282630
Jun. 10, 2025 (DE) 1020251225435

(51) Int. Cl. H01L 23/66; H01P 3/00; H01P 3/12; H01Q 13/00

(52) U.S. Cl. CPC H10W 44/20; H01P 3/003; H01P 3/121; H01Q 13/00; H10W 44/216; H10W 44/248

(57) ABSTRACT

A radio frequency (RF) device includes at least one RF chip, including a local oscillator configured to generate an RF signal. The RF device further includes an RF signal path coupling an output of the at least one RF chip and an input of the at least one RF chip, wherein the RF signal path is configured to feed the generated RF signal from the output of the at least one RF chip into the input of the at least one RF chip. The RF device further includes a processing unit coupled to the input of the at least one RF chip and configured to perform in a first mode at least one of testing, monitoring or calibrating the at least one RF chip based on the generated RF signal.

### CROSS-REFERENCE TO RELATED APPLICATIONS

This application claims priority to Germany Patent Application No. 102024128263.0 filed on Sep. 30, 2024, and Germany Patent Application No. 102025122543.5 filed on Jun. 10, 2025, the contents of which are incorporated by reference herein in their entirety.

### TECHNICAL FIELD

The present disclosure relates to radio frequency (RF) devices and methods for manufacturing RF devices.

### BACKGROUND

Radar systems may include one or multiple RF transceiver chips. However, single RF transceiver chips may only include a limited number of virtual array elements. In order to meet the requirements of certain applications, such as e.g., autonomous driving, multiple RF transceiver chips may thus be cascaded and synchronized as a single unit. Usually, a cascading of multiple RF transceiver chips is carried out on a printed circuit board which may require a comparatively large amount of space. Appropriate testing, monitoring and calibration of the RF transceiver chips may be required in order to ensure proper operation of the radar systems.

Manufacturers and developers of RF devices are constantly striving to improve their products. In this regard, it may be desirable to provide RF devices with improved performance, smaller size and reduced cost. In addition, it may be desirable to provide suitable methods for manufacturing such RF devices.

### SUMMARY

An aspect of the present disclosure relates to an RF device. The RF device includes at least one RF chip, including a local oscillator configured to generate an RF signal. The RF device further includes an RF signal path coupling an output of the at least one RF chip and an input of the at least one RF chip, wherein the RF signal path is configured to feed the generated RF signal from the output of the at least one RF chip into the input of the at least one RF chip. The RF device further includes a processing unit coupled to the input of the at least one RF chip and configured to perform in a first mode at least one of testing, monitoring or calibrating the at least one RF chip based on the generated RF signal.

A further aspect of the present disclosure relates to an RF device. The RF device includes at least one RF chip, including a TX channel for a transmission of RF signals and an RX channel for a reception of RF signals. The RF device further includes an RF signal path coupling an output of the TX channel and an input of the RX channel. The RF signal path is configured to feed an RF signal from the output of the TX channel into the input of the RX channel.

A further aspect of the present disclosure relates to a method for manufacturing an RF device. The method includes arranging at least one RF chip, including a local oscillator configured to generate an RF signal. The method further includes coupling an output of the at least one RF chip and an input of the at least one RF chip by an RF signal path, wherein the RF signal path is configured to feed the generated RF signal from the output of the at least one RF chip into the input of the at least one RF chip. The method further includes coupling a processing unit to the input of the at least one RF chip, wherein the processing unit is configured to perform in a first mode at least one of testing, monitoring or calibrating the at least one RF chip based on the generated RF signal.

A further aspect of the present disclosure relates to a method for manufacturing an RF device. The method includes arranging at least one RF chip, including a TX channel for a transmission of RF signals and an RX channel for a reception of RF signals. The method further includes coupling an output of the TX channel and an input of the RX channel by an RF signal path. The RF signal path is configured to feed an RF signal from the output of the TX channel into the input of the RX channel.

Those skilled in the art will recognize additional features and advantages upon reading the following detailed description, and upon viewing the accompanying drawings.

### BRIEF DESCRIPTION OF THE DRAWINGS

The present disclosure is illustrated by way of example, and not by way of limitation, in the figures of the accompanying drawings in which like reference numerals refer to similar or identical elements. The elements of the drawings are not necessarily to scale relative to each other. The features of the various illustrated examples can be combined unless they exclude each other.

FIG. 1 schematically illustrates a cross-sectional side view of an RF device 100 in accordance with the disclosure.

FIG. 2 schematically illustrates a top view of an RF device 200 in accordance with the disclosure.

FIG. 3 schematically illustrates a cross-sectional side view of an RF device 300 in accordance with the disclosure.

FIG. 4 schematically illustrates a cross-sectional side view of an RF device 400 in accordance with the disclosure.

FIG. 5 schematically illustrates a cross-sectional side view of an RF device 500 in accordance with the disclosure.

FIG. 6 schematically illustrates a top view of an RF device 600 in accordance with the disclosure.

FIG. 7 schematically illustrates a cross-sectional side view of an RF device 700 in accordance with the disclosure.

FIG. 8 schematically illustrates a cross-sectional side view of an RF device 800 in accordance with the disclosure.

FIG. 9 schematically illustrates a cross-sectional side view of an RF device 900 in accordance with the disclosure.

FIG. 10 illustrates a flowchart of a method for manufacturing an RF device in accordance with the disclosure.

FIG. 11 illustrates a flowchart of a method for manufacturing an RF device in accordance with the disclosure.

### DETAILED DESCRIPTION

In the following detailed description, reference is made to the accompanying drawings, in which are shown by way of illustration specific aspects in which the disclosure may be practiced. Other aspects may be utilized and structural or logical changes may be made without departing from the concept of the present disclosure. Hence, the following detailed description is not to be taken in a limiting sense, and the concept of the present disclosure is defined by the appended claims.

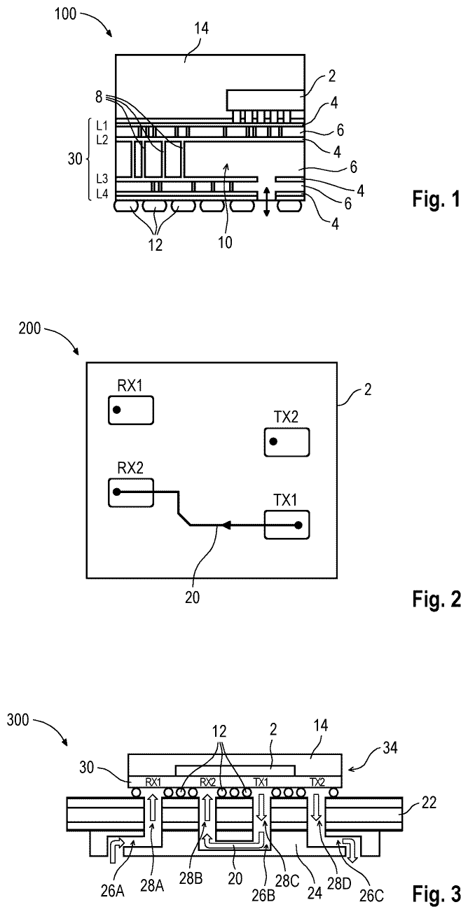

Referring now to FIG. 1, an RF device 100 in accordance with the disclosure is shown. The RF device 100 may include at least one RF chip 2 configured to provide or support at least one transmit (TX) channel for transmitting RF signals and at least one receive (RX) channel for receiving RF signals. In the illustrated example, a single RF chip 2 is shown, but it is to be understood that the RF device 100 may include additional RF chips, the number of which may depend on a specific design of the RF device 100. The RF chip 2 may be made of or may include an arbitrary semiconductor material, such as e.g., silicon. The RF chip 2 (or electronic circuits thereof) may be configured to operate in a frequency range of greater than about 1 GHz, in some examples greater than about 10 GHz. Accordingly, the RF chip 2 may also be referred to as radio frequency chip or high frequency chip or microwave frequency chip. More particular, the RF chip 2 may be configured to operate in an RF range or microwave frequency range, which may range from about 1 GHz to about 1 THz, more particular from about 10 GHz to about 300 GHz. Microwave circuits may include, for example, microwave transmitters, microwave receivers, microwave transceivers, microwave sensors, microwave detectors, or the like. RF devices in accordance with the disclosure may be used for radar applications in which the frequency of the RF signals may be modulated. The RF chip 2 may therefore also be referred to as radar chip. In particular, the RF chip 2 may include or may correspond to an MMIC (Monolithic Microwave Integrated Circuit).

Radar microwave devices may e.g., be used in automotive, industrial, military and/or defense applications for range and speed measuring systems. For example, automotive applications may include advanced driver assistant systems, automatic vehicle cruise control systems, vehicle anti-collision systems, or the like. Such systems may operate in the microwave frequency range and may utilize FMCW (Frequency Modulation Continuous Wave) signals, for example in the 24 GHz, 76 GHz, or 79 GHz frequency bands. A use of radar microwave systems may provide constant and efficient driving of vehicles. An efficient driving style may, for example, reduce fuel consumption such that CO₂ emission may be reduced and energy savings may be enabled. In addition, abrasion of vehicle tires, brake discs and brake pads may be reduced, thereby reducing fine dust pollution. Improved RF or radar systems, as described herein, may thus contribute to green technology solutions, e.g., climate-friendly solutions providing reduced energy usage.

The RF chip 2 may include at least one local oscillator (not illustrated) configured to generate a local oscillator RF signal. The RF chip 2 may use the local oscillator RF signal for operations such as transmitting signals or mixing with received signals. For example, the local oscillator RF signal may be mixed with a received RF signal using a mixer to down-convert the frequency of the received RF signal to a more manageable range. In particular, an incoming RF signal may be mixed with the local oscillator RF signal in order to produce an intermediate (IF) frequency signal. The local oscillator RF signal may be used to shift the frequency of the received RF signal to a frequency range that can be easily processed by the receiver and subsequent processing stages of the RF device 100. The local oscillator RF signal may be or may include a mm-wave local oscillator signal. In some applications, the local oscillator RF signal may be or may include an FMCW-signal including a plurality of frequency ramps. The local oscillator RF signal may be based on a reference clock. In this regard, the RF device 100 may include a crystal oscillator (not illustrated) configured to generate the reference clock and to provide the reference clock to the RF chip 2. In general, a frequency of the RF signal generated by the local oscillator may be greater than a frequency of the reference clock. In a non-limiting and example case, the reference clock may have a frequency of about 50 MHz.

In the illustrated example, the RF device 100 may correspond to or may include a flip-chip package, but is not restricted thereto. The RF chip 2 may be mounted on a top surface of a substrate 30. The substrate 30 may include multiple metal layers 4 (see L1 to L4) and multiple dielectric layers 6 arranged between the multiple metal layers 4. The metal layers 4 and the dielectric layers 6 may substantially extend in a direction parallel to a main surface of the RF chip 2. The metal layers L2 and L3 may be electrically connected in the vertical direction by multiple via connections 8. Optionally, similar via connections may provide an electrical connection in the vertical direction between the metal layers L1 and L2 and between the metal layers L3 and L4.

The RF device 100 may include at least one substrate integrated waveguide (SIW) 10 configured for transmitting mm-wave signals in particular. The SIW 10 may include the metal layers L2 and L3 as well as the dielectric layer 6 arranged between the metal layers L2 and L3. In addition, the SIW 10 may include the plurality of via connections 8 extending between the metal layers L2 and L3. The via connections 8 may be arranged to form a via fence. The SIW 10 may be formed by the dielectric layer 6 covered on both faces by the metal layers L2 and L3. The dielectric layer 6 may embed the via connections 8 that may form two parallel rows of metallic via holes delimiting a propagation area of RF signals (e.g., electromagnetic waves) that are to be transmitted via the SIW 10. The propagating electromagnetic waves may be confined within the dielectric layer 6 by the metal layers L2 and L3 on each of the two surfaces of the dielectric layer 6 as well as between the two rows of metallic vias 8 connecting the metal layers L2 and L3. In the illustrated example, the SIW 10 may be configured to transmit electromagnetic waves in a lateral direction. It is to be noted that a radar operation and/or a transmission of RF signals of RF devices as described herein is not restricted to be provided by way of SIWs. That is, in the example of FIG. 1 or any other implementation as described herein, a transmission of RF signals may also be provided by one or more transmission lines or any other suitable structure capable of transmitting RF signals.

The RF device 100 may include an AFIP (Antenna Feed in Package). The AFIP may include a first launcher coupled to an RF port of the RF chip 2 to transfer an RF signal between the RF port and a waveguide antenna (not shown) which may, for example, be arranged below the bottom surface of the substrate 30. A launcher of the RF device 100 may be configured to couple a signal from the SIW 10 into a waveguide (such as e.g., an air-filled waveguide) external to the RF device 100 and/or from the external waveguide into the SIW 10. The launcher may include at least one coupling element that may e.g., be formed in the metal layer L3. For example, the coupling element may include or may correspond to one or multiple antennas, such as e.g., patch antennas. In the illustrated example, a launcher may be arranged substantially at the right end of the SIW 10. A coupling of RF signals from the SIW 10 into an external waveguide and/or vice versa is exemplarily indicated by a bidirectional vertical arrow.

During operation of the RF device 100, RF signals processed by the RF chip 2 may be transmitted to the launcher via the SIW 10. In this context, the RF device 100 may further include at least one planar transmission line (such as e.g., at least one coplanar waveguide, CPW) which may be at least partially formed in the metal layers L1 and/or L2 and may be configured to couple the RF chip 2 and the SIW 10. For example, an RF signal may be coupled from the planar transmission line into the SIW 10 via a slot antenna that may be formed in the metal layer L2. The launcher may then transmit the RF signals received from the SIW 10, for example into a waveguide antenna. In a similar fashion, the RF device 100 may receive RF signals during operation, for example by coupling the RF signals from a waveguide antenna to the launcher. The received RF signals may then be forwarded to the RF chip 2 via the SIW 10 and the planar transmission line.

The RF device 100 may include at least one coupling element 12 configured to mechanically and/or electrically couple the RF device 100 to an external component, such as e.g., a printed circuit board (PCB) (not illustrated). In the illustrated example, the coupling elements 12 may include or may correspond to a plurality of solder balls which may be arranged at the bottom surface of the substrate 30. Furthermore, the RF device 100 may include an encapsulation material (or package body) 14 in which the RF chip 2 and other components of the RF device 100 may be embedded. The RF device 100 may also be referred to as package, semiconductor package, RF package or semiconductor RF package. For example, the encapsulation material 14 may include or may be made of at least one of a molding compound, an epoxy, an imide, a thermoplast, a thermoset polymer, a polymer blend, or the like, and may e.g., be manufactured based on an appropriate molding technique.

Referring now to FIG. 2, an RF device 200 in accordance with the disclosure is shown. The RF device 200 may include some or all features of the RF device 100 of FIG. 1. In some examples, FIG. 2 may be seen as a (cross-sectional) top view of the RF device 100 of FIG. 1. In the illustrated example, the RF device 200 may include an RF chip 2 providing an example and non-limiting number of two TX channels TX1-TX2 and two RX channels RX1-RX2. However, it is to be understood that the RF chip 2 may include an arbitrary number of additional TX and/or RF channels. In the illustrated example, RF ports of associated RF channels are indicated by dots, while small rounded squares surrounding the dots may indicate coupling structures, such as e.g., launchers. A transmission of RF signals via a TX channel of the RF device 200 is now exemplarily described for the TX channel TX2. An RF signal processed by the RF chip 2 may be transmitted to an SIW via a planar transmission line which may be formed in the metal layers L1 and/or L2. The RF signal may be coupled into the SIW delimited by via connections via a slot antenna which may be formed in metal layer L2. The RF signal may be transmitted via the SIW to a launcher (such as e.g., a patch antenna) which may be formed in metal layer L3. The launcher may couple the RF signal out of the RF device 200, for example into a waveguide antenna. An example reception of RF signals via an RX channel of the RF device 200 may be similar and is now exemplarily described for the RX channel RX1. An RF signal may be received at a launcher (e.g., from a waveguide antenna) and may be transmitted towards the RF chip 2 via an SIW. The RF signal may be coupled from the SIW to a planar transmission line by a slot antenna and may then be transmitted to the RF chip 2 via the planar transmission line.

As can be seen from FIG. 2, the RF device 200 may include an RF signal path 20 coupling an output and an input of the same RF chip 2. That is, the RF signal path 20 may be configured to feed an RF signal from an output of the RF chip 2 into an input of the RF chip 2. In particular, the RF signal may be or may include an RF signal generated by a local oscillator of the RF chip 2 as previously discussed in connection with FIG. 1. In the illustrated example, RF signals of the TX channel TX1 may be fed into the RX channel RX2. That is, the TX channel TX1 is not used in a usual sense for broadcasting RF signals (such as e.g., into a waveguide antenna), but is fed back into the RF chip 2 for further processing. In the shown case, the RF signal path 20 may include an SIW similar to FIG. 1. Referring back to the example of FIG. 1, the SIW may be arranged in the substrate 30 on which the RF chip 2 may be arranged. However, it is to be understood that in further examples, a loopback of RF signals from an output of the RF chip 2 into an input of the RF chip 2 may be provided in a different fashion as described in more detail below. It is to be noted that loopbacks of RF signals as described herein are not restricted to be provided by way of SIWs. That is, the RF signal path 20 shown as a line in FIG. 2 does not necessarily represent an SIW. For instance, in the example of FIG. 2 or any other implementation as described herein, a loopback may also be provided by one or more transmission lines or any other suitable structure capable of transmitting RF signals.

The RF devices 100 and 200 may include a processing unit (not illustrated) coupled to the input of the RF chip 2 where the fed back RF signal may be received. A coupling between the processing unit and the RF chip 2 may be established by at least one of a signal line, a planar transmission line, a waveguide, etc. For example, the processing unit may include or may correspond to at least one of a microcontroller, a digital signal processor, or the like. The processing unit may be part of the RF chip 2 or may correspond to a separate component. The processing unit may be configured to perform in a first mode at least one of testing, monitoring or calibrating the RF chip 2 based on the RF signal fed back into the RF chip 2. In this regard, the processing unit may, for example, perform at least one of short-range leakage cancellation, blocker cancellation, target monitoring, functional safety checking, phase noise estimation, phase noise monitoring, etc. In particular, the first mode performed by the processing unit may particularly differ from a second mode for synchronizing the at least one RF chip 2 based on a local oscillator RF signal described later on.

In an illustrative and non-limiting example, at least one of a short-range leakage cancellation or a phase noise estimation may be performed based on a fed back local oscillator RF signal. In radar systems the overall noise floor may limit a target detection sensitivity and accuracy of a distance estimation. In general, the noise floor may be dominated by the additive noise of the channel. However, in case a close target (such as e.g., a bumper) reflects the radar waves with high amplitude, the phase noise of the transmitted carrier may dominate the noise floor. This in turn may deteriorate signal detection quality or may even prohibit a detection of targets with small radar cross sections at all. In this regard, the term short-range leakage cancellation may refer to an approach to estimate and cancel the signal reflections from such close targets. In addition to short-range leakage cancellation, phase noise estimation and phase noise monitoring is also of importance for the radar system.

In the context of short-range leakage cancellation and phase noise estimation, an RF device in accordance with the disclosure may include a time delay element (not illustrated) which may be at least partially formed by the RF signal path 20. The time delay element may be configured to apply a delay to the fed back RF signal to generate a delayed RF signal. The time delay element may include or may correspond to an artificial radar target configured to apply an attenuation to the fed back RF signal to generate an attenuated RF signal. The processing unit of the RF device 200 may then be configured to perform at least one of a phase noise estimation or a short-range leakage cancellation based on the delayed and attenuated RF signal mimicking the effect of a close target. A person skilled in the art may be familiar with appropriate algorithms or calculation schemes performed by the processing unit for short-range leakage cancellation and phase noise estimation. It is to be understood that the described short-range leakage cancellation and a phase noise estimation may be performed by RF devices including a single RF chip, but may also be performed by RF devices including a plurality of RF chips, such as e.g., cascaded RF systems.

Referring now to FIG. 3, an RF device 300 in accordance with the disclosure is shown. The RF device 300 may include some or all features of previously described RF devices. The RF device 300 may include a package or RF package 34 similar to e.g., the RF device 100 of FIG. 1. In the illustrated example side view, an example number of two TX channels TX1, TX2 and two receive channels RX1, RX2 of the RF package 34 are shown. However, it is to be understood that the RF device 300 may provide one or more additional TX channels and/or RX channels. RF signals associated with the TX and RX channels may be transmitted and received using launchers that may be arranged at the bottom surface of the RF package 34 as previously described in connection with FIGS. 1 and 2. Note that the substrate 30 of the RF package 34 may contain one or more SIWs similar to previous examples which are not illustrated for the sake of simplicity.

In the illustrated example, the RF package 34 may be mounted on a top surface of a printed circuit board (PCB) 22 which may be regarded as part of the RF device 300 in some examples. The RF device 300 may include a waveguide antenna 24 which may be mounted on the bottom surface of the PCB 22. The waveguide antenna 24 may include a plurality of waveguides 26A to 26C formed inside the waveguide antenna 24. In the illustrated example, the waveguides 26A to 26C of the waveguide antenna 24 may include or may correspond to air-filled waveguides. The PCB 22 may include multiple openings 28A to 28D extending from the top surface of the PCB 22 to the bottom surface of the PCB 22. The openings 28A to 28D may be aligned with the launchers arranged at the bottom surface of the RF package 34 and the waveguides 26A to 26C formed in the waveguide antenna 24. During an operation of the RF device 300, RF signals may be received by a waveguide 26A on the left and coupled into the substrate 34 via a launcher aligned with the left opening 28A of the PCB 22 (see RX1). In a similar fashion, RF signals that are to be transmitted may be coupled into a waveguide 26C on the right from a launcher aligned with the right opening 28D of the PCB 22 (see TX2).

Similar to the example of FIG. 2, the RF device 300 may include an RF signal path 20 coupling an output of the RF chip 2 and an input of the RF chip 2, wherein the RF signal path 20 may be configured to loop back an RF signal generated by a local oscillator of the RF chip 2 from the output of the RF chip 2 into the input of the RF chip 2. In the illustrated example, the output of the RF chip 2 may be associated with TX channel TX 1 while the input may be associated with RX channel RX2 of the RF chip 2. In the shown case, the RF signal path 20 may include a waveguide 26B formed in the waveguide antenna 24. The fed back RF signal may be provided to a processing unit to perform in a first mode at least one of testing, monitoring or calibrating the RF chip 2 based on the fed back RF signal as previously described.

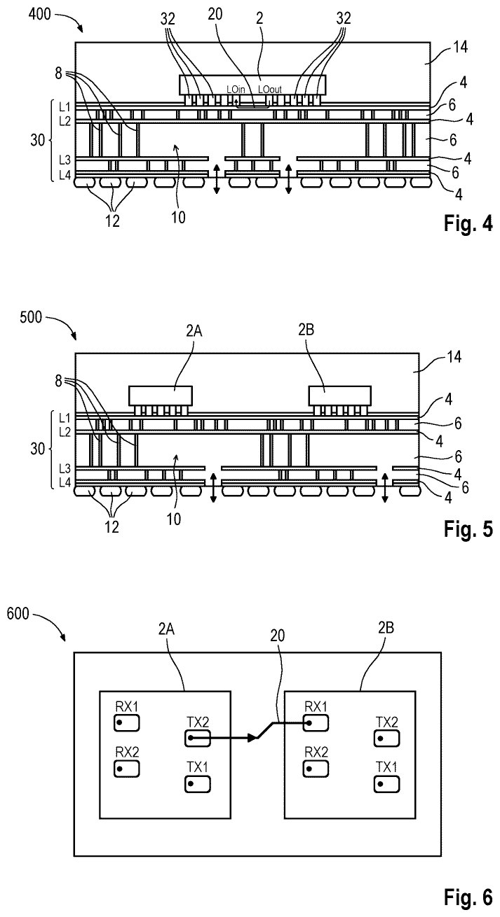

Referring now to FIG. 4, a further RF device 400 in accordance with the disclosure is shown. The RF device 400 may include some or all features of previously described RF devices. In particular, the RF device 400 may be at least partially similar to the RF device 100 of FIG. 1. Similar to previous examples, an RF signal may be fed from an output of an RF chip 2 into an input of the RF chip 2. In the illustrated example, the RF chip 2 of the RF device 400 may include a plurality of chip contacts 32 arranged at the bottom surface of the RF chip 2 facing the top surface of the substrate 30. The chip contacts 32 may include one or more inputs of the RF chip 2 and one or more outputs of the RF chip 2. The RF chip 2 may include at least one dedicated local oscillator input (see LOin) and at least one dedicated local oscillator output (see LOout). An RF signal path 20 may couple an output of the RF chip 2 and an input of the RF chip 2, wherein the RF signal path 20 may be configured to feed an RF signal from the output of the RF chip 2 into the input of the RF chip 2 similar to previous examples. More particular, the RF signal path 20 may be configured to loop back a generated local oscillator RF signal from the local oscillator output (see LOout) into the local oscillator input (see LOin). In the shown case, the RF signal path 20 may include a planar transmission line which may be arranged in or on the substrate 30. In one example, the planar transmission line may be formed in the metal layers L1 and/or L2 of the substrate 30.

The term dedicated local oscillator inputs/outputs may refer to dedicated inputs/outputs of an RF chip for transmitting and receiving local oscillator RF signals. In RF devices, these local oscillator RF signals may be used for synchronization purposes. For example, in RF devices including multiple RF chips (such as cascaded RF devices), the RF chips may be synchronized in order to make the cascaded RF system operate as a single RF system in which each of the RF channels has a predefined phase relation to each other. For achieving appropriate synchronization between different RF chips, local oscillator signals may be shared between a primary RF chip (or master) and secondary RF chips (or slaves) of the RF device. In this context, the primary RF chip may be configured to generate a local oscillator signal which may be shared across all RF chips in the entire cascaded RF system. In other words, the at least one secondary RF chip will use the local oscillator signal generated by the primary RF chip for operations such as transmitting signals or mixing with received signals rather than generating and using an unsynchronized local oscillator signal on their own. In this context, the RF chips of the RF device may include dedicated local oscillator inputs and dedicated local oscillator outputs for realizing the specified synchronization. An RF chip used in a standalone configuration (e.g., not being part of a cascaded RF system) may include one or more unused dedicated local oscillator inputs and/or local oscillator outputs.

Similar to previous examples, the RF device 400 may include a processing unit configured to perform in a first mode at least one of testing, monitoring or calibrating the RF chip 2 based on the generated local oscillator RF signal which is fed back into the RF chip 2 as previously described in connection with FIG. 2. It is to be noted that the first mode performed by the processing unit may particularly differ from a second mode for synchronizing the at least one RF chip 2 based on the generated RF signal as described before.

Referring now to FIG. 5, an RF device 500 in accordance with the disclosure is shown. The RF device 500 may include some or all features of previously described RF devices. In particular, the RF device 500 may be at least partially similar to the RF device 100 of FIG. 1. In the illustrated example, the RF device 500 may include at least two RF chips 2A, 2B, which may be mounted on the top surface of the substrate 30. For example, the at least two RF chips 2A, 2B may form a cascaded RF system. The RF device 500 may include multiple launchers arranged at the bottom surface of the substrate 30 for transmitting and receiving RF signals. In the illustrated example, multiple RF chips 2A, 2B may be embedded within the same package. The RF device 500 may include an RF path for a loopback of RF signals in the package as will be described in the following in connection with FIG. 6.

Referring now to FIG. 6, an RF device 600 in accordance with the disclosure is shown. The RF device 600 may include some or all features of the RF device 500 of FIG. 5. In the illustrated example, the RF device 600 may include at least two RF chips 2A, 2B, which may be part of a cascaded RF system. Each of the RF chips 2A, 2B may include or provide an example and non-limiting number of two TX channels TX1-TX2 and two RX channels RX1-RX2. However, it is to be understood that the RF chips 2A, 2B may include an arbitrary number of additional TX and/or RF channels. Similar to the example of FIG. 2, RF ports of associated RF channels are indicated by dots, while rounded squares may indicate coupling structures, such as e.g., launchers. An example transmission of RF signals via a TX channel and an example reception of RF signals via an RX channel have been previously described in connection with FIG. 2.

As can be seen from FIG. 6, the RF device 600 may include an RF signal path 20 coupling an output of the first RF chip 2A and an input of the second RF chip 2B, wherein the RF signal path 20 may be configured to feed an RF signal from the output of the first RF chip 2A into the input of the second RF chip 2B. In particular, the RF signal may be generated by a local oscillator included in the first RF chip 2A. In the illustrated example, RF signals of the TX channel TX2 of the first chip 2A may be fed into the RX channel RX1 of the second chip 2B. That is, the TX channel TX2 of the first RF chip 2A is not necessarily used in a usual sense for broadcasting RF signals (such as e.g., into a waveguide antenna), but fed into the second RF chip 2B for further processing. In one example, the RF signal path 20 may include an SIW. Referring back to the example of FIG. 5, the SIW 10 may be arranged in the substrate 30. However, it is to be understood that in further examples, feeding RF signals from an output of a first RF chip into an input of a second RF chip may be established differently.

Similar to previous examples, the RF device 600 may include a processing unit (not illustrated) coupled to the input of the second RF chip 2B. For example, the processing unit may include or may correspond to at least one of a microcontroller, a digital signal processor, or the like. The processing unit may be configured to perform in a first mode at least one of testing, monitoring or calibrating at least one of the RF chips 2A, 2B based on the local oscillator RF signal generated by the local oscillator of the first RF chip 2A fed back into the RF chip 2. In some examples, a second local oscillator may be arranged in the second RF chip 2B and configured to generate a second local oscillator signal. The processing unit may then be configured to perform in the first mode at least one of testing, monitoring or calibrating at least one of the first RF chip 2A or the second RF chip 2B based on both the first local oscillator RF signal generated in the first RF chip 2A and the second local oscillator RF signal generated in the second RF chip 2B. It is to be noted that the first mode performed by the processing unit may particularly differ from a second mode for synchronizing the RF chips 2A, 2B based on local oscillator RF signals as previously described in connection with FIG. 4.

In an illustrative and non-limiting example, in the first mode, a phase noise may be estimated based on the two local oscillator signals generated in the two RF chips 2A, 2B such that a phase noise monitoring may be performed. For example, the RF chips 2A, 2B may correspond to a master MMIC and a slave MMIC of a cascaded RF system which may be involved in the measurement of a phase noise estimation mode simultaneously. In such case, both RF chips 2A, 2B may use their internal local oscillators to generate individual FMCW (Frequency Modulated Continuous Wave) signals. The generated local oscillator signals may be mixed and low-pass filtered in the slave MMIC. The resulting signal may be further processed in order to estimate the mean phase noise (PN) power spectral density (PSD) between the involved MMICs. The PN PSD may be used to detect whether one or both of the involved MMICs generate phase noise out of specification. A person skilled in the art may be familiar with appropriate algorithms or calculation schemes performed by the processing unit for such phase noise estimation. It is noted that that the described phase noise estimation and phase noise monitoring may particularly be performed by RF devices including at least two RF chips, such as e.g., a cascaded RF system.

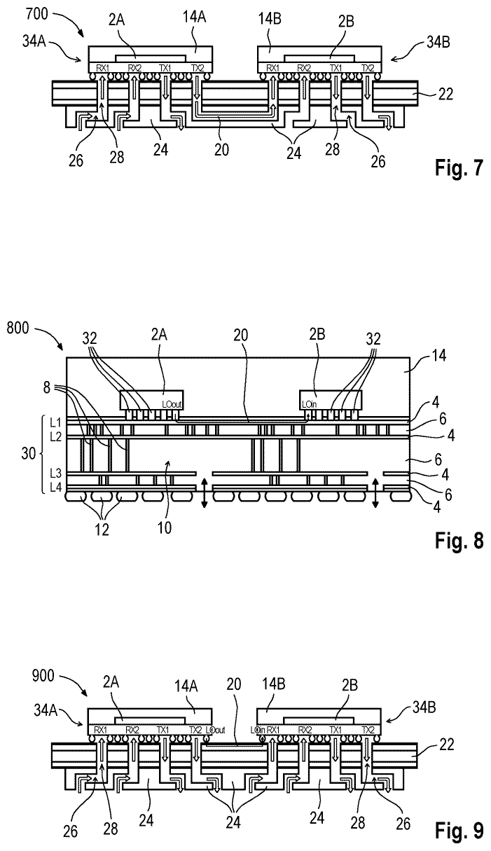

Referring now to FIG. 7, an RF device 700 in accordance with the disclosure is shown. The RF device 700 may include some or all features of previously described RF devices. The RF device 700 may include at least two RF packages 34A, 34B similar to e.g., the RF device 100 of FIG. 1. The first RF package 34A may include at least one first RF chip 2A, while the second RF package 34B may include at least one second RF chip 2B. In the illustrated side view, an example number of two TX channels TX1, TX2 and two receive channels RX1, RX2 are shown for each of the RF chips 2A, 2B. However, it is to be understood that the RF device 700 may include additional RF packages, and/or the RF chips 2A, 2B may provide additional TX channels and/or RX channels. RF signals associated with the TX and RX channels may be transmitted and received using launchers that may be arranged at the bottom surfaces of the packages 34A, 34B.

In the illustrated example, the RF packages 34A, 34B may be mounted on a top surface of a PCB 22 which may be regarded as part of the RF device 700 in some examples. The RF device 700 may include a waveguide antenna 24 mounted on the bottom surface of the PCB 22. The waveguide antenna 24 may include a plurality of waveguides 26 formed inside the waveguide antenna 24. In the illustrated example, the waveguides 26 of the waveguide antenna 24 may include or may correspond to air-filled waveguides. The PCB 22 may include multiple openings 28 extending from the top surface of the PCB 22 to the bottom surface 22 of the PCB 22. The openings 28 may be aligned with the launchers arranged at the bottom surface of the RF packages 34A, 34B and may also be aligned with the waveguides 26 of the waveguide antenna 24.

The RF device 700 may include an RF signal path 20 coupling an output of the first RF chip 2A and an input of the second RF chip 2B, wherein the RF signal path 20 may be configured to feed an RF signal generated by a local oscillator of the first RF chip 2A from the output of the first RF chip 2A into the input of the second RF chip 2B. In the illustrated example, the output of the first RF chip 2A is an output of TX channel TX2 of the first RF chip 2A, and the input of the second RF chip 2B is an input of RX channel RX1 of the second RF chip 2B. The RF signal path 20 may be configured to feed the generated local oscillator RF signal from the output of TX channel TX2 into the input of RX channel RX1. In the shown case, the RF signal path 20 may include a waveguide 26 formed in the waveguide antenna 24. Similar to previous examples, the RF device 700 may include a processing unit (not illustrated) coupled to the input of the second RF chip 2B and configured to perform in a first mode at least one of testing, monitoring or calibrating the at least one RF chip based on the generated RF signal.

Referring now to FIG. 8, a further RF device 800 in accordance with the disclosure is shown. The RF device 800 may include some or all features of previously described RF devices. In particular, the RF device 800 may be at last partially similar to the RF device 500 of FIG. 5. Similar to the previous examples, an RF signal may be fed from an output of a first RF chip 2A into an input of a second RF chip 2B. In the illustrated example, each of the RF chips 2A and 2B may include a plurality of chip contacts 32 arranged at the bottom surface of the respective RF chip. The chip contacts 32 may include one or more inputs of a respective RF chip and one or more outputs of a respective RF chip. The first RF chip 2A may include at least one dedicated local oscillator output (see LOout), and the second RF chip 2B may include at least one dedicated local oscillator input (see LOin). Similar to previous examples, an RF signal path 20 may be configured to feed a local oscillator RF signal from the output of the first RF chip 2A into the input of the second RF chip 2B. More particular, the RF signal path 20 may be configured to feed the RF signal from the local oscillator output (see LOout) of the first RF chip 2A into the local oscillator input (see LOin) of the second RF chip 2B. In the shown example, the RF signal path 20 may include a planar transmission line which may be arranged in or on the substrate 30. For example, the planar transmission line may be formed in the metal layers L1 and/or L2 of the substrate 30.

Referring now to FIG. 9, an RF device 900 in accordance with the disclosure is shown. The RF device 900 may include some or all features of previously described RF devices. In particular, the RF device 900 may be at least partially similar to the RF device 700 of FIG. 7. Similar to previous examples, the RF device 900 may include an RF signal path 20 coupling an output of a first RF chip 2A and an input of a second RF chip 2B, wherein the RF signal path 20 may be configured to feed a generated local oscillator RF signal from the output of the first RF chip 2A into the input of the second RF chip 2B. In the illustrated example, the RF signal path 20 may be configured to feed the generated RF signal from a dedicated local oscillator output (see LOout) of the first RF chip 2A into a dedicated local oscillator input (see LOin) of the second RF chip 2B. In the shown case, the RF signal path 20 may include a planar transmission line which may be arranged in or on the printed circuit board 22.

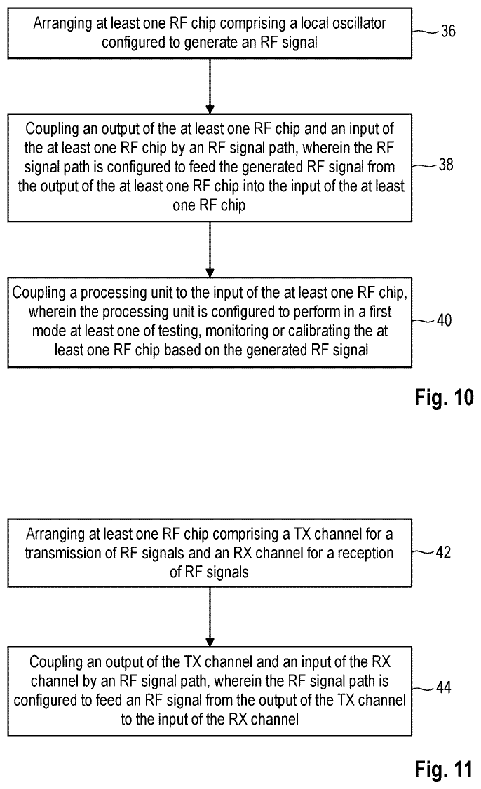

FIG. 10 illustrates a flowchart of a method for manufacturing an RF device in accordance with the disclosure. The method may be used for manufacturing RF devices as previously described and may thus be read in connection with previous figures. The method is described in a general manner in order to qualitatively specify aspects of the disclosure. It is to be understood that the method may include further aspects. For example, the method may be extended by any of the aspects described in connection with other examples in accordance with the disclosure.

At 36, at least one RF chip may be arranged, wherein the at least one RF chip may include a local oscillator configured to generate an RF signal. At 38, an output of the at least one RF chip and an input of the at least one RF chip may be coupled by an RF signal path, wherein the RF signal path may be configured to feed the generated RF signal from the output of the at least one RF chip into the input of the at least one RF chip. In a first example, the term “at least one RF chip” may refer to a single RF chip. Here, an output of the single RF chip may be coupled to an input of the same single RF chip. In a further example, the term “at least one RF chip” may refer to multiple RF chips. Here, an output of a first RF chip of the multiple RF chips may be coupled to an input of a second RF chip of the multiple RF chips different from the first RF chip. At 40, a processing unit may be coupled to the input of the at least one RF chip, wherein the processing unit may be configured to perform in a first mode at least one of testing, monitoring or calibrating the at least one RF chip based on the generated RF signal. For example, a coupling between the processing unit and the at least one RF chip may be established by a signal line, a planar transmission line, a waveguide, etc.

FIG. 11 illustrates a flowchart of a method for manufacturing an RF device in accordance with the disclosure. The method may be used for manufacturing RF devices as previously described and may thus be read in connection with previous figures. The method is described in a general manner in order to qualitatively specify aspects of the disclosure. It is to be understood that the method may include further aspects. For example, the method may be extended by any of the aspects described in connection with other examples in accordance with the disclosure.

At 42, at least one RF chip may be arranged, wherein the at least one RF chip may include a TX channel for a transmission of RF signals and an RX channel for a reception of RF signals. At 44, an output of the TX channel and an input of the RX channel may be coupled by an RF signal path. The RF signal path may be configured to feed an RF signal from the output of the TX channel into the input of the RX channel.

### EXAMPLES

The examples described herein provide RF devices and methods for manufacturing RF devices.

Example 1 is an RF device, comprising: at least one RF chip, comprising a local oscillator configured to generate an RF signal; an RF signal path coupling an output of the at least one RF chip and an input of the at least one RF chip, wherein the RF signal path is configured to feed the generated RF signal from the output of the at least one RF chip into the input of the at least one RF chip; and a processing unit coupled to the input of the at least one RF chip and configured to perform in a first mode at least one of testing, monitoring or calibrating the at least one RF chip based on the generated RF signal.

Example 2 is an RF device of Example 1, further comprising: a second mode different from the first mode for synchronizing the at least one RF chip based on the generated RF signal.

Example 3 is an RF device of Example 1 or 2, wherein the output and the input of the at least one RF chip are part of a same RF chip.

Example 4 is an RF device of Example 3, further comprising: a time delay element at least partially formed by the RF signal path and configured to apply a delay to the generated RF signal to generate a delayed RF signal.

Example 5 is an RF device of Example 4, wherein: the time delay element is an artificial radar target configured to apply an attenuation to the generated RF signal to generate an attenuated RF signal, and the processing unit is configured to perform at least one of a phase noise estimation or a short-range leakage cancellation based on the delayed and attenuated RF signal.

Example 6 is an RF device of Example 1 or 2, wherein the output of the at least one RF chip is part of a first RF chip and the input of the at least one RF chip is part of a second RF chip.

Example 7 is an RF device of Example 6, wherein the first RF chip and the second RF chip are part of a cascaded RF system.

Example 8 is an RF device of Example 6 or 7, wherein: the local oscillator is arranged in the first RF chip, a further local oscillator is arranged in the second RF chip and configured to generate a further RF signal, and the processing unit is configured to perform in the first mode at least one of testing, monitoring or calibrating the first RF chip and the second RF chip based on the two generated RF signals.

Example 9 is an RF device of any of the preceding Examples, wherein: the output of the at least one RF chip is an output of a transmit (TX) channel of the at least one RF chip and the input of the at least one RF chip is an input of a receive (RX) channel of the at least one RF chip, and the RF signal path is configured to feed the generated RF signal from the output of the TX channel into the input of the RX channel.

Example 10 is an RF device of any of Examples 1 to 8, wherein: the output of the at least one RF chip is a dedicated local oscillator (LO) output and the input of the at least one RF chip is a dedicated LO input, and the RF signal path is configured to feed the generated RF signal from the LO output into the LO input.

Example 11 is an RF device of any of the preceding Examples, wherein the RF signal path comprises a substrate integrated waveguide.

Example 12 is an RF device of Example 11, further comprising: a substrate, wherein the at least one RF chip is arranged on the substrate and the substrate integrated waveguide is arranged in the substrate.

Example 13 is an RF device of any of the preceding Examples, wherein the RF signal path comprises a waveguide formed in a waveguide antenna.

Example 14 is an RF device of Example 13, further comprising: a printed circuit board, wherein the at least one RF chip and the waveguide antenna are arranged on opposite sides of the printed circuit board, wherein a first opening of the printed circuit board is aligned with the output of the at least one RF chip and a second opening of the printed circuit board is aligned with the input of the at least one RF chip.

Example 15 is an RF device of any of the preceding Examples, wherein the RF signal path comprises a planar transmission line.

Example 16 is an RF device of Example 15, further comprising: a substrate, wherein the at least one RF chip is arranged on the substrate and the planar transmission line is arranged in or on the substrate.

Example 17 is an RF device of Example 15, further comprising: a printed circuit board, wherein the at least one RF chip is arranged on the printed circuit board and the planar transmission line is arranged in or on the printed circuit board.

Example 18 is an RF device, comprising: at least one RF chip, comprising a TX channel for a transmission of RF signals and an RX channel for a reception of RF signals; and an RF signal path coupling an output of the TX channel and an input of the RX channel, wherein the RF signal path is configured to feed an RF signal from the output of the TX channel into the input of the RX channel.

Example 19 is an RF device of Example 18, wherein the output of the TX channel and the input of the RX channel are part of a same RF chip.

Example 20 is an RF device of Example 18, wherein the output of the TX channel is part of a first RF chip and the input of the RX channel is part of a second RF chip.

Example 21 is an RF device of any of Examples 18 to 20, further comprising: a substrate, wherein the at least one RF chip is arranged on the substrate, and wherein the RF signal path comprises a substrate integrated waveguide arranged in the substrate.

Example 22 is an RF device of any of Examples 18 to 21, further comprising: a waveguide antenna, wherein the RF signal path comprises a waveguide formed in the waveguide antenna; and a printed circuit board, wherein the at least one RF chip and the waveguide antenna are arranged on opposite surfaces of the printed circuit board, wherein a first opening of the printed circuit board is aligned with the output of the TX channel and a second opening of the printed circuit board is aligned with the input of the RX channel.

Example 23 is a method for manufacturing an RF device, the method comprising: arranging at least one RF chip, comprising a local oscillator configured to generate an RF signal; coupling an output of the at least one RF chip and an input of the at least one RF chip by an RF signal path, wherein the RF signal path is configured to feed the generated RF signal from the output of the at least one RF chip into the input of the at least one RF chip; and coupling a processing unit to the input of the at least one RF chip, wherein the processing unit is configured to perform in a first mode at least one of testing, monitoring or calibrating the at least one RF chip based on the generated RF signal.

Example 24 is a method for manufacturing an RF device, the method comprising: arranging at least one RF chip, comprising a TX channel for a transmission of RF signals and an RX channel for a reception of RF signals; and coupling an output of the TX channel and an input of the RX channel by an RF signal path, wherein the RF signal path is configured to feed an RF signal from the output of the TX channel into the input of the RX channel.

As employed in this specification, the terms “connected”, “coupled”, “electrically connected”, and/or “electrically coupled” may not necessarily mean that elements must be directly connected or coupled together. Intervening elements may be provided between the “connected”, “coupled”, “electrically connected”, or “electrically coupled”elements.

Furthermore, to the extent that the terms “having”, “containing”, “including”, “with”, or variants thereof are used in either the detailed description or the claims, such terms are intended to be inclusive in a manner similar to the term “comprising”. That is, as used herein, the terms “having”, “containing”, “including”, “with”, “comprising”, and the like are open-ended terms that indicate the presence of stated elements or features, but do not preclude additional elements or features. The articles “a”, “an”, and “the” are intended to include the plural as well as the singular, unless the context clearly indicates otherwise.

Moreover, the words “example” and “example” are used herein to mean serving as an example, instance, or illustration. Any aspect or design described herein as “example” or “example” is not necessarily to be construed as advantageous over other aspects or designs. Rather, use of the words “example” and “example” is intended to present concepts in a concrete fashion. As used in this application, the term “or” is intended to mean an inclusive “or” rather than an exclusive “or”. That is, unless specified otherwise, or clear from context, “X employs A or B” is intended to mean any of the natural inclusive permutations. That is, if X employs A; X employs B; or X employs both A and B, then “X employs A or B” is satisfied under any of the previous instances. In addition, the articles “a” and “an” as used in this application and the appended claims may generally be construed to mean “one or multiple” unless specified otherwise or clear from context to be directed to a singular form. Also, at least one of A and B or the like generally means A or B or both A and B.

Although specific examples have been illustrated and described herein, it will be appreciated by those of ordinary skill in the art that a variety of alternate and/or equivalent implementations may be substituted for the specific examples shown and described without departing from the scope of the present implementation. This application is intended to cover any adaptations or variations of the specific examples discussed herein. Therefore, it is intended that this implementation be limited only by the claims and the equivalents thereof.

It should be noted that the methods and devices including its preferred implementations as outlined in the present document may be used stand-alone or in combination with the other methods and devices disclosed in this document. In addition, the features outlined in the context of a device are also applicable to a corresponding method, and vice versa. Furthermore, all aspects of the methods and devices outlined in the present document may be arbitrarily combined. In particular, the features of the claims may be combined with one another in an arbitrary manner.

It should be noted that the description and drawings merely illustrate the principles of the proposed methods and systems. Those skilled in the art will be able to implement various arrangements that, although not explicitly described or shown herein, embody the principles of the implementation and are included within its spirit and scope. Furthermore, all examples and implementations outlined in the present document are principally intended expressly to be only for explanatory purposes to help the reader in understanding the principles of the proposed methods and systems. Furthermore, all statements herein providing principles, aspects, and implementations of the implementation, as well as specific examples thereof, are intended to encompass equivalents thereof.

1. A radio frequency (RF) device, comprising:
at least one RF chip comprising a local oscillator configured to generate an RF signal;
an RF signal path coupling an output of the at least one RF chip and an input of the at least one RF chip, wherein the RF signal path is configured to feed the RF signal from the output of the at least one RF chip into the input of the at least one RF chip; and
a processing unit coupled to the input of the at least one RF chip and configured to perform, in a first mode, at least one of testing, monitoring, or calibrating the at least one RF chip based on the RF signal.

2. The RF device of claim 1, wherein the processing unit is configured to, in a second mode that is different from the first mode, synchronize the at least one RF chip based on the RF signal

3. The RF device of claim 1, wherein the output and the input of the at least one RF chip are parts of a same RF chip.

4. The RF device of claim 3, further comprising:
a time delay element at least partially formed by the RF signal path and configured to apply a delay to the RF signal to generate a delayed RF signal.

5. The RF device of claim 4, wherein:
the time delay element is an artificial radar target configured to apply an attenuation to the RF signal to generate a delayed and attenuated RF signal, and
the processing unit is configured to perform at least one of a phase noise estimation or a short-range leakage cancellation based on the delayed and attenuated RF signal.

6. The RF device of claim 1, wherein the output of the at least one RF chip is part of a first RF chip and the input of the at least one RF chip is part of a second RF chip.

7. The RF device of claim 6, wherein the first RF chip and the second RF chip are part of a cascaded RF system.

8. The RF device of claim 6, wherein:
the local oscillator is arranged in the first RF chip,
a further local oscillator is arranged in the second RF chip and configured to generate a further RF signal, and
the processing unit is configured to perform, in the first mode, at least one of testing, monitoring, or calibrating the first RF chip and the second RF chip based on the RF signal and the further RF signal.

9. The RF device of claim 1, wherein:
the output of the at least one RF chip is an output of a transmit (TX) channel of the at least one RF chip and the input of the at least one RF chip is an input of a receive (RX) channel of the at least one RF chip, and
the RF signal path is configured to feed the RF signal from the output of the TX channel into the input of the RX channel.

10. The RF device of claim 1, wherein:
the output of the at least one RF chip is a dedicated local oscillator (LO) output and the input of the at least one RF chip is a dedicated LO input, and
the RF signal path is configured to feed the RF signal from the dedicated LO output into the dedicated LO input.

11. The RF device of claim 1, wherein the RF signal path comprises a substrate integrated waveguide.

12. The RF device of claim 11, further comprising:
a substrate, wherein the at least one RF chip is arranged on the substrate and the substrate integrated waveguide is arranged in the substrate.

13. The RF device of claim 1, wherein the RF signal path comprises a waveguide formed in a waveguide antenna.

14. The RF device of claim 13, further comprising:
a printed circuit board,
wherein the at least one RF chip and the waveguide antenna are arranged on opposite sides of the printed circuit board, and
wherein a first opening of the printed circuit board is aligned with the output of the at least one RF chip and a second opening of the printed circuit board is aligned with the input of the at least one RF chip.

15. The RF device of claim 1, wherein the RF signal path comprises a planar transmission line.

16. The RF device of claim 15, further comprising:
a substrate, wherein the at least one RF chip is arranged on the substrate and the planar transmission line is arranged in or on the substrate.

17. The RF device of claim 15, further comprising:
a printed circuit board, wherein the at least one RF chip is arranged on the printed circuit board and the planar transmission line is arranged in or on the printed circuit board.

18. A radio frequency (RF) device, comprising:
at least one RF chip comprising a transmit (TX) channel for a transmission of RF signals and a receive (RX) channel for a reception of the RF signals; and
an RF signal path coupling an output of the TX channel and an input of the RX channel,
wherein the RF signal path is configured to feed an RF signal from the output of the TX channel into the input of the RX channel.

19. The RF device of claim 18, wherein the output of the TX channel and the input of the RX channel are parts of a same RF chip.

20. The RF device of claim 18, wherein the output of the TX channel is part of a first RF chip and the input of the RX channel is part of a second RF chip.

21. The RF device of claim 18, further comprising:
a substrate,
wherein the at least one RF chip is arranged on the substrate, and
wherein the RF signal path comprises a substrate integrated waveguide arranged in the substrate.

22. The RF device of claim 18, further comprising:
a waveguide antenna, wherein the RF signal path comprises a waveguide formed in the waveguide antenna; and
a printed circuit board,
wherein the at least one RF chip and the waveguide antenna are arranged on opposite surfaces of the printed circuit board, and
wherein a first opening of the printed circuit board is aligned with the output of the TX channel and a second opening of the printed circuit board is aligned with the input of the RX channel.

23. A method for manufacturing a radio frequency (RF) device, the method comprising:
arranging at least one RF chip comprising a local oscillator configured to generate an RF signal;
coupling an output of the at least one RF chip and an input of the at least one RF chip by an RF signal path, wherein the RF signal path is configured to feed the RF signal from the output of the at least one RF chip into the input of the at least one RF chip; and
coupling a processing unit to the input of the at least one RF chip, wherein the processing unit is configured to perform, in a first mode, at least one of testing, monitoring, or calibrating the at least one RF chip based on the RF signal.

24. A method for manufacturing a radio frequency (RF) device, the method comprising:
arranging at least one RF chip comprising a transmit (TX) channel for a transmission of RF signals and a receive (RX) channel for a reception of the RF signals; and
coupling an output of the TX channel and an input of the RX channel by an RF signal path,
wherein the RF signal path is configured to feed an RF signal from the output of the TX channel into the input of the RX channel.
